(19) United States
(12) Patent Application Publication
(10) Pub. No.: US 2004/0216173 A1
(43) Pub. Date: Oct. 28, 2004

(54) Video archiving and processing method and apparatus

(76) Inventors: Peter Horoszowski, Jackson Heights, NY (US); George Grippo, Rockaway, NJ (US); Andrew Samaan, New York, NY (US); Scott Spector, New York, NY (US)

Correspondence Address: R. Neil Sudol, 714 Colorado Avenue, Bridgeport, CO, 06605, US

(21) Appl. No.: 10/412,744

(22) Filed: Apr. 11, 2003

(51) Int. Cl. H04N 7/173; H01L 21/00; H01L 21/82; H04N 7/16

(52) U.S. Cl. 725/145; 438/13; 438/128; 725/115; 725/135; 715/500.1; 715/512

(57) ABSTRACT

In a video archiving and processing method, plural low-resolution video data streams in different formats are generated from an incoming stream of high-resolution video frame data. One of the low-resolution video data streams is a storyboard in the form of a low-resolution video data stream wherein successive frames each correspond to a respective different scene of the high-resolution video frame data. This storyboard is generated by a computer programmed to automatically identify scene changes in successive frames encoded in the video frame data.

### BACKGROUND OF THE INVENTION

This invention relates to a video archiving and processing method. This invention also relates to an associated apparatus.

The amount of video recordings made annually is increasing at a geometric or exponential rate. Video programs transmitted via networks, cables and satellite are all being archived for future reference. Broad categories of video programs include news, political and economic commentaries, sports, comedy, drama, documentaries, nature, children's shows, educational shows, and miscellaneous entertainment.

The sheer quantity of the recordings gives rise to several problems. One set of problems relates to the archiving process: adequate storage capacity, storage speed, and reliability and longevity. Another set of problems relates to use of the archived video assets: retrieval speed, transmission speed, editing capabilities, etc.

A particular set of problems pertains to accessing of the stored video materials. How is the material to be organized to facilitate retrieval? If searchable indices are used, how are the indices generated?

### OBJECTS OF THE INVENTION

It is an object of the present invention to provide an improved video archiving and processing method and/or associated apparatus.

It is another object of the present invention to provide a video archiving and processing method and/or associated apparatus that may facilitate distribution of video data over a network such as the Internet.

A more particular object of the present invention is to provide a video archiving and processing method and/or associated apparatus wherein archiving speed is enhanced.

Another object of the present invention is to provide a video archiving and processing method and/or associated apparatus wherein editing is facilitated.

An additional object of the present invention is to provide a video archiving and processing method and/or associated apparatus wherein the production of video clips is facilitated.

These and other objects of the invention will be apparent from the drawings and descriptions herein. Although each object is achieved by at least one embodiment of the invention, there is not necessarily any single embodiment that achieves all of the objects of the invention.

### SUMMARY OF THE INVENTION

A video archiving and processing method comprises, in accordance with the present invention, providing a stream of high-resolution video frame data, operating at least one digital computer to automatically identify scene changes in successive frames encoded in the video frame data, automatically generating a storyboard in the form of a low-resolution video data stream wherein successive frames each correspond to a respective different scene of the high-resolution video frame data, and storing the high-resolution video frame data and the low-resolution video data stream.

Pursuant to alternative specific features of the present invention, the computer automatically identifies scene changes by analyzing changes in color and/or illumination intensity or by conducting a vector analysis of successive frames of the video frame data. Alternatively or additionally, the storyboard may be generated by detecting time code in the video frame data.

The storyboard may be one of a plurality of low-resolution video data streams in different formats that the one or more computers automatically generate from an incoming stream of high-resolution video data. The low-resolution video data streams may be derived from a high-resolution version (e.g., MPEG-1 or MPEG-2) of the video frame data. One or more of the low-resolution video data streams may be stored in a digital or solid-state memory. The high-resolution version and possibly one or more low-resolution versions are generally stored on magnetic tape or video disc.

The operating of the computer(s) may include selecting sets of transcode rules from a store of possible rules to create transcode profiles for respective ones of the low-resolution video data streams, the transcode profiles corresponding to respective formats. The computer is operated to generate the low-resolution video data streams in accordance with the respective transcode profiles. The transcode profiles may be generated in accordance with predetermined kinds of formats of possible interest to clients or customers of a video archiving and processing business. Alternatively or additionally, transcode profiles may be created in response to transcode-profile instructions received from an individual user computer.

Pursuant to further features of the present invention, a video clip is generated from a high-resolution version of video frame data, the video clip having a defined in-point or starting frame and a defined out-point or end frame. The video clip is stored and also transmitted to another computer in response to a request from a client or customer computer. Typically, the request is received from the user computer via the Internet. In addition, the video clip may be transmitted via that global computer network to the user computer or another computer designated by the user, subscriber, or client. The video clip may be a high-resolution data stream of any format or a low-resolution data stream of any format.

The video clip may be generated in response to edit instructions received from a user computer. The instructions may identify a stored video asset from which the video clip is to be made. Typically, the video asset is a high-resolution version of an ingested video frame data stream. The client instructions also designate the in-point and out-point of the video asset, which will respectively constitute the starting frame and end frame of the video clip. In addition, the instructions from the user computer may specify a name for the video clip. Optionally, the user computer may provide instructions for generating or editing textual material to be transmitted with or as part of the video clip.

Pursuant to additional features of the present invention, the client drafts the edit instructions by reviewing one of the stored low-resolution video data streams in lieu of the stored high-resolution version of the video frame data. In this scenario, in response to a request for a stored low-resolution data stream received from the user computer, at least a portion of the requested low-resolution data stream is transmitted to the user computer, for instance, via the Internet. Subsequently, the edit instructions, exemplarily in the form of an edit decision request, are received from the user computer.

A video archiving and processing method comprises, in accordance with another embodiment of the present invention, providing a stream of high-resolution video frame data, operating at least one digital computer to automatically generate, from the stream of video frame data, at least one low resolution video data stream, providing textual material corresponding to at least some frames of the high-resolution video frame data, storing the textual material, automatically generating a searchable index of the textual material, and storing the index. The index preferably includes identification codes (e.g., time codes) associating the textual material with selected frames of the low-resolution video data stream, the identification codes being stored together with the searchable index.

In accordance with a further feature of the present invention, the textual material is automatically extracted from text data included in the high-resolution video data. Such text data may include closed caption data and/or subtitles. Alternatively or additionally, the textual material may be input from a source other than the high-resolution video data. The textual material may include annotations related to subject matter of the high-resolution video data.

Another feature of the present invention pertains to user editing of stored textual material and/or indices thereof. In response to a request from a user computer, a selected portion of stored textual material (e.g., annotations) is transmitted to the user computer. Subsequently, in response to an edit request received from the user computer, an edited version of the portion of the stored textual material is stored.

A video processing method comprises, in accordance with another embodiment of the present invention, storing a high-resolution version and a low-resolution version of a video asset, transmitting at least a portion of the low-resolution version of the video asset across a network in response to a request from a user computer via the network, subsequently receiving edit instructions from the user computer pertaining to the video asset, producing a video clip derived from the high-resolution version of the video asset in response to the received editing instructions, and transmitting the high-resolution version video clip over the network. The video clip may be high resolution or low resolution and in any known format. Typically, particularly for short clips (.e.g, a single scene) the clip may be in a high-resolution format. The video clip may be transmitted to a target address and at a transmission time specified by instructions received from the user computer.

As discussed above, the invention contemplates an automatic generation of the low-resolution version from the high-resolution version. The low-resolution version may be a storyboard version in the form of a sequence of video frames representing respective scenes of the video asset.

As also discussed above, a searchable index of textual material may be automatically generated from the textual material, while the textual material may be stored together with the index and identification codes associating the textual material with portions of the video asset. The index is accessed in response to a request from the user computer.

A video processing method comprises, in accordance with yet another embodiment of the present invention, storing (i) a high-resolution version of a video asset, (ii) a low-resolution version of the video asset, (iii) textual material pertaining to the video asset; and (iv) a searchable index of the textual material. This method additionally comprises transmitting across a network, in response to a request received from a user computer via the network, at least one of (a) a portion of the low-resolution version of the video asset, (b) a portion of the textual material, and (c) a portion of the index. Subsequently, edit instructions are received from the user computer to generate a video clip in any given format from the high-resolution version of the video asset. Prior to reception of the edit instructions, a retrieval of the high-resolution version from storage is commenced.

A video archiving and processing apparatus comprises, in accordance with a feature of the present invention, a video input receiving a stream of high-resolution video frame data and at least one digital computer operatively connected to the video input for analyzing the stream of high-resolution video frame data to automatically identify scene changes in successive frames encoded in the video frame data and for automatically generating a storyboard in the form of a low-resolution video data stream wherein successive frames each correspond to a respective different scene of the high-resolution video frame data. A memory is operatively connected to the computer for storing the high-resolution video frame data and the low-resolution video data stream. The computer may be programmed to generate a searchable index of textual material corresponding to at least some frames of the high-resolution video frame data, where the index includes identification codes associating the textual material with selected frames of the low-resolution video data stream. The computer may be further programmed to automatically extract the textual material from text data included in the high-resolution video data.

A video archiving and processing apparatus comprises, in accordance with another feature of the present invention, a video input receiving a stream of high-resolution video frame data and at least one digital computer operatively connected to the video input for generating, from the stream of video frame data, a plurality of low-resolution video data streams in respective formats different from each other. A memory is operatively connected to the computer for storing the low-resolution data streams and a high-resolution version of the video frame data.

A video processing apparatus comprises, in accordance with yet another feature of the present invention, a memory storing a high-resolution version and a low-resolution version of a video asset and an interface for receiving a request from a user computer via a network. The interface is operatively connected to the memory for extracting at least a portion of the low-resolution version of the video asset from the memory and transmitting the portion of the low-resolution version of the video asset across the network. An editing tool is operatively connected to the interface and the memory for generating, in response to editing instructions received from the user computer over the network, a video clip, exemplarily a high-resolution video clip, from the high-resolution version of the video asset.

A video processing apparatus comprises, in accordance with yet a further feature of the present invention, a memory, an interface, and a memory access unit, where the memory stores (i) a high-resolution version of a video asset, (ii) a low-resolution version of the video asset, (iii) textual material pertaining to the video asset; and (iv) a searchable index of the textual material. The interface is disposed for receiving a request from a user computer via a network and is connected to the memory for accessing the memory to transmit, in response to the request and across the network, at least one of (a) a portion of the low-resolution version of the video asset, (b) a portion of the textual material, and (c) a portion of the index. The memory access unit is operatively connected to the memory and the interface for commencing a retrieval of the high-resolution version from the memory upon the receiving of the request and prior to the receiving of edit instructions from the user computer to generate a video clip from the high-resolution version of the video asset.

### BRIEF DESCRIPTION OF THE DRAWING

FIGS. 1A-1F are a combined flow chart and system diagram showing different operations in a video archiving and processing method in accordance with the present invention and further showing various hardware components which carry out or execute the operations.

FIG. 2 is a more detailed block diagram of a video archiving and processing system in accordance with the present invention.

FIG. 3 is a block diagram of selected components of FIG. 2, showing further components for enabling a user or customer to participate in video processing and transmitting operations, the components typically being realized as generic digital computer circuits modified by programming to performed respective functions.

FIG. 4 is a block diagram of selected modules of a user or client computer for enabling accessing of video and related textual material in the system of FIGS. 1-3, the modules typically being realized as generic digital computer circuits modified by programming to performed respective functions.

FIG. 5 is a block diagram of components of a scene change analyzer illustrated in FIG. 2, the components typically being realized as generic digital computer circuits modified by programming to performed respective functions.

### DEFINITIONS

The word “metadata” refers herein to information relating to a video asset and more particularly to information over and beyond video images. Metadata generally occurs in the form of textual material, i.e., in alphanumeric form. Metadata or textual material may be encoded in a video signal as closed captioning or subtitles. Alternatively, metadata may be conveyed via flat files (excel, word, etc.), hand-written notes, still images, scripts, logs, run-downs, etc.

The verb “transcode” refers herein to the conversion of a media file from one format, most commonly a high-resolution master file, to one or more lower bit-rate proxies or representations.

The term “transcode profile” is used herein to designate a collection of transcode rules that are applied to a file or piece of media at the time of ingestion.

The term “transcode rules” as used herein denotes a single set of parameters or steps that are applied to a transcode application to define what characteristics the proxy should have.

A “transcoder” as that term is used herein pertains to a piece of hardware, which can be a computer running a number of different operating systems, that takes a master file as input and puts out a lower resolution or lower bit-rate proxy. Transcoder rules are typically written following a standard XML (Extensible Markup Language) a growing standard in the computer industry. Accordingly, transcode rules may be termed an “XML rule set.”

The term “modified XML rule set” is used herein to denote the modification of an XML transcoding rule set based on initial metadata assigned to the asset. For example, during creation of an internet resolution file, an embedded watermark could be placed within a video clip that contains some field of data entered such as the length of the clip.

The term “edit decision” is used herein to describe the contents of an assembled video clip. The term “edit decision list” (edl) refers to a list of video clips in order with name of clip, time-code in-point, and time-code outpoint, as well as any notes for transitions or fade in and fade out descriptors.

The word “edit” is used more broadly herein to denote changes or modifications made to a video file or a text file. The term “edit request” or “edit instructions” refers to an order or request placed by a client or customer for changes in stored video data or stored textual material. The changes prescribed by an edit request or instruction may result in the generation of a new entity based on stored video data or stored textual material. For instance, an edit instruction may result in the generation of a video clip or a storyboard from a stored data stream. In that case, the order or request may take a form specifying a video asset, an in-point, an out-point, and a name for the video clip.

The word “annotation” as used herein designates metadata that is tied to a specific second or frame of video. More particularly, “annotation” is typically used for scene descriptions, close captioned text, or sports play information.

The word “script” refers to text descriptor or dialogue of a piece of video.

The acronym “ODBC” stands for “open database connectivity” which is a standard communication protocol that allows various databases, such as Oracle, Microsoft SQL, Informix, etc., to communicate with applications.

The term “video frame data” is used herein to denote video data including a succession of video frames reproducible as scenes of a moving video image.

The word “scene” is used herein to designate a series of related frames encoded in a video data stream, where the differences between consecutive frames are incremental only. Thus, where there is a scene change, there is more than an incremental change in video image between consecutive frames of a video data stream. A scene change may occur by change of viewing angle, magnification, illumination, color, etc., as well as by a change in pictured subject matter. As disclosed herein, a scene change may be automatically detected by a computer executing a vector analysis algorithm or by computer tracking of color distribution or average light intensity.

The term “client computer” as used herein denotes a computer owned and operated by an entity using a video archiving and processing service as described herein. It is contemplated that a client computer communicates with the archiving and video processing computers via a network such as the Internet.

The term “time code positioning command” is used herein to denote an offset time that allows for playing video from the middle of a stream, for instance, after the first five minutes of a stored video clip.

### DETAILED DESCRIPTION OF THE PREFERRED EMBODIMENTS

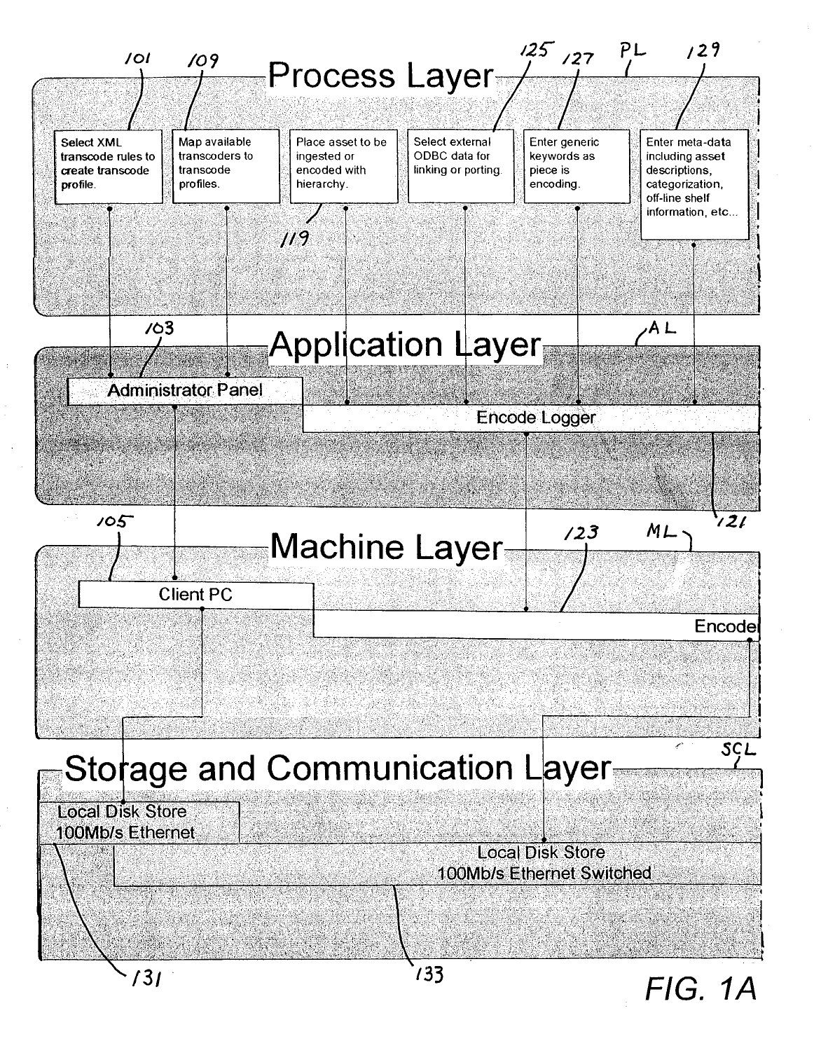

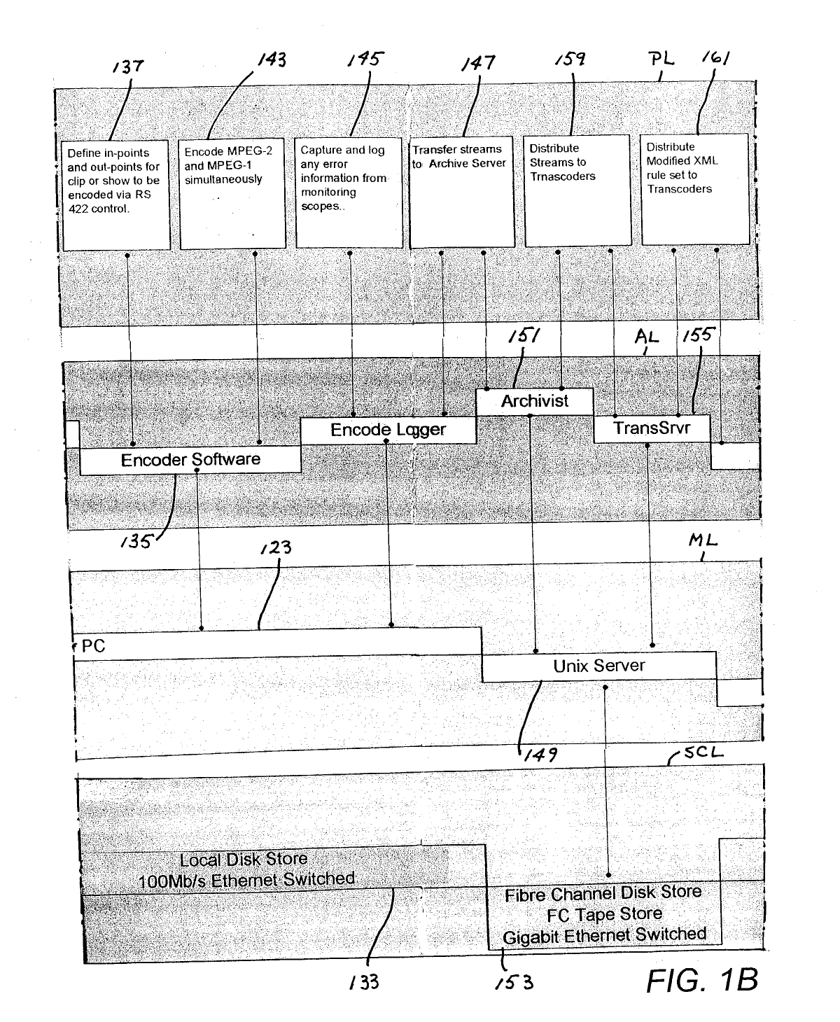

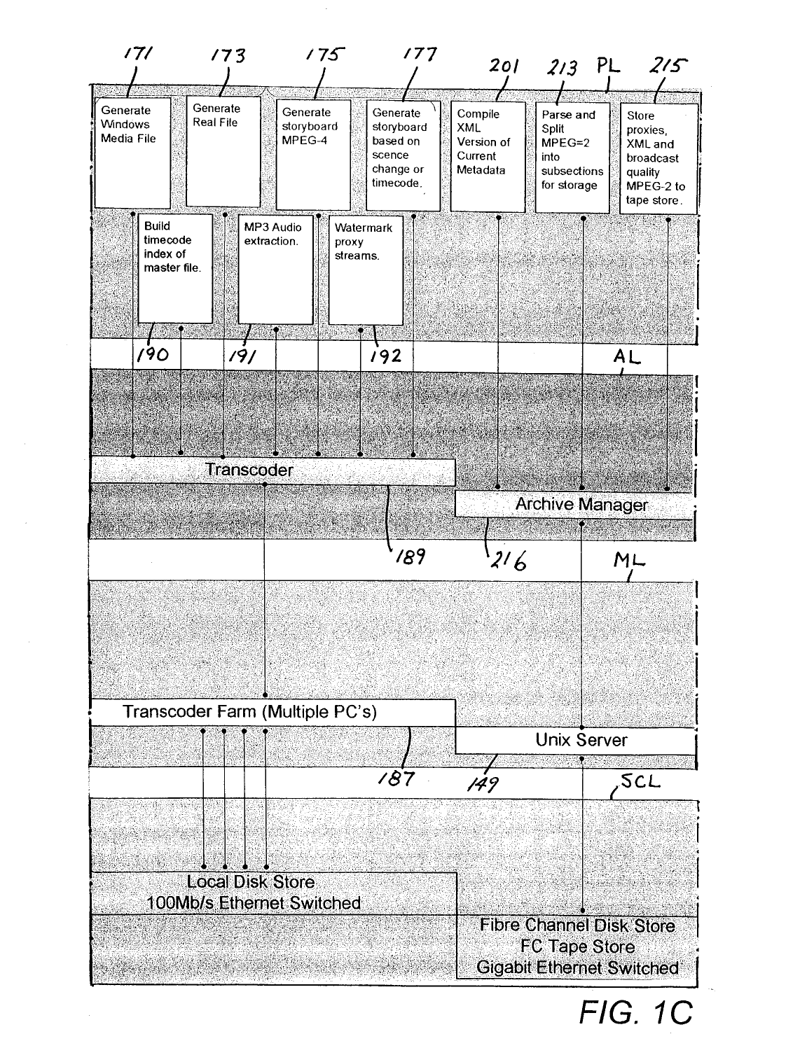

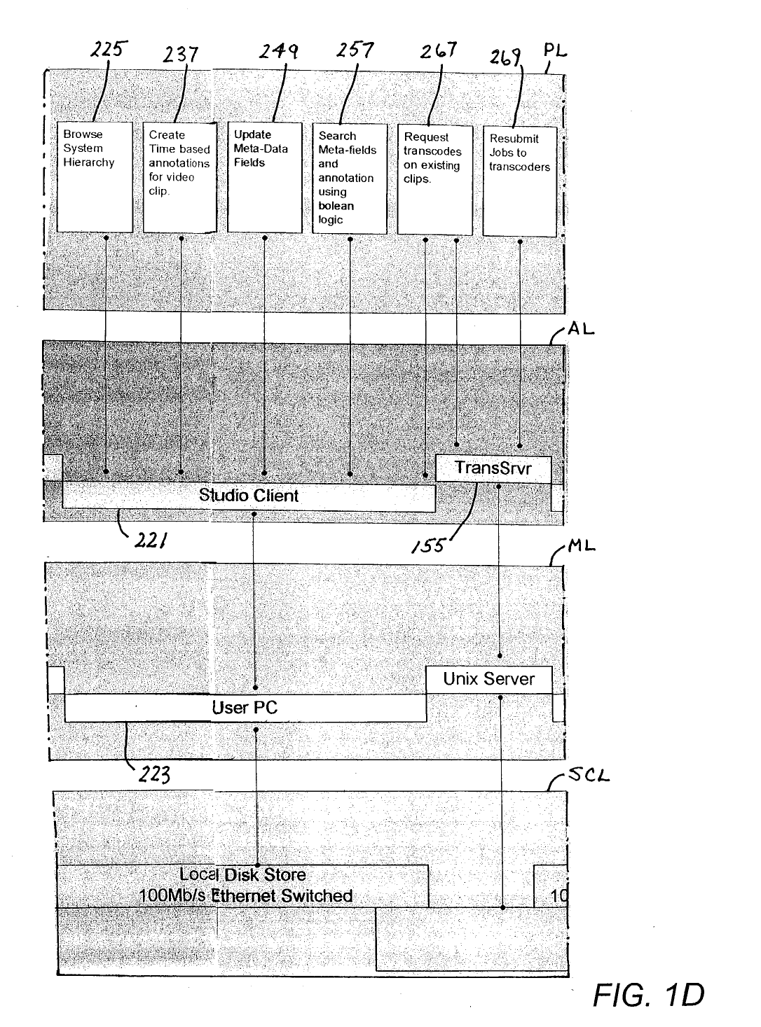

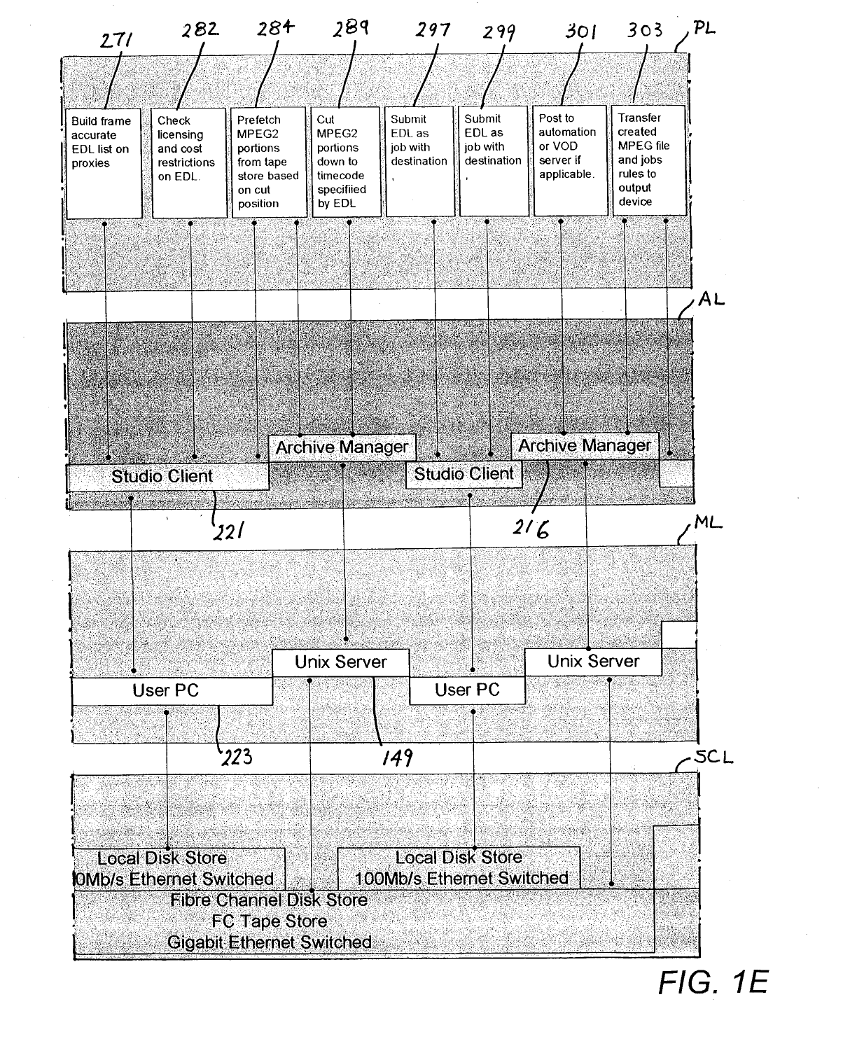

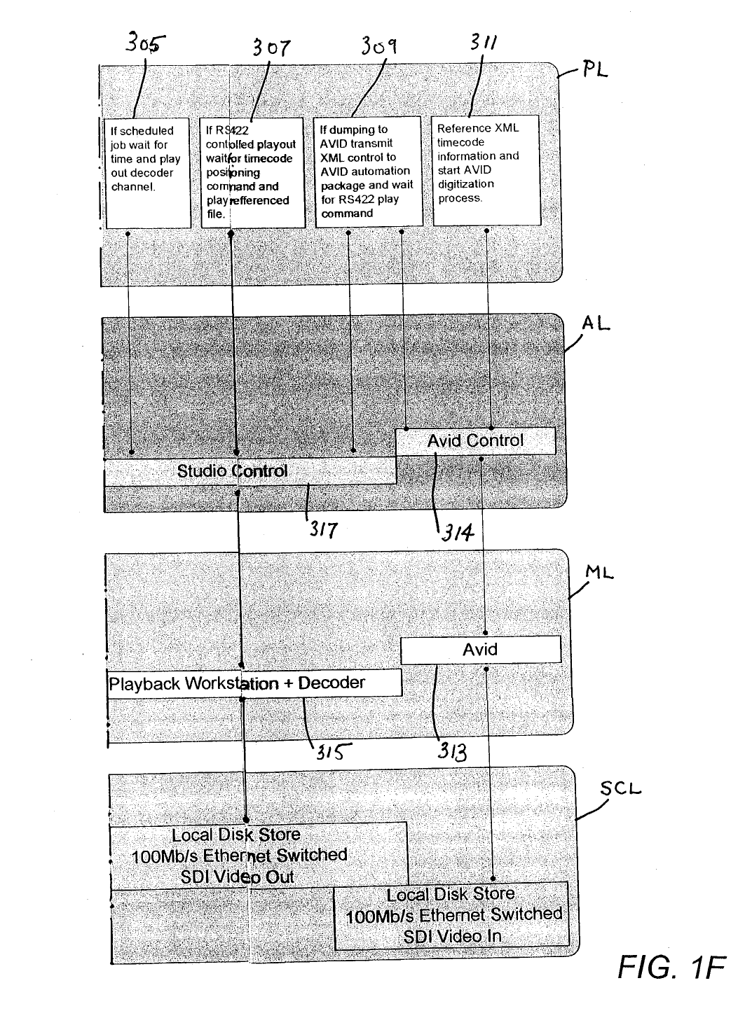

FIGS. 1A through 1F illustrate, in a process layer PL, various operational steps performed by in a video archiving and processing system. Programs or software carrying out the steps of process layer PL are depicted in an underlying applications layer AP, while the hardware on which the applications software is running is shown in a machine layer ML. Ancillary equipment is illustrated in a storage and communication layer SCL.

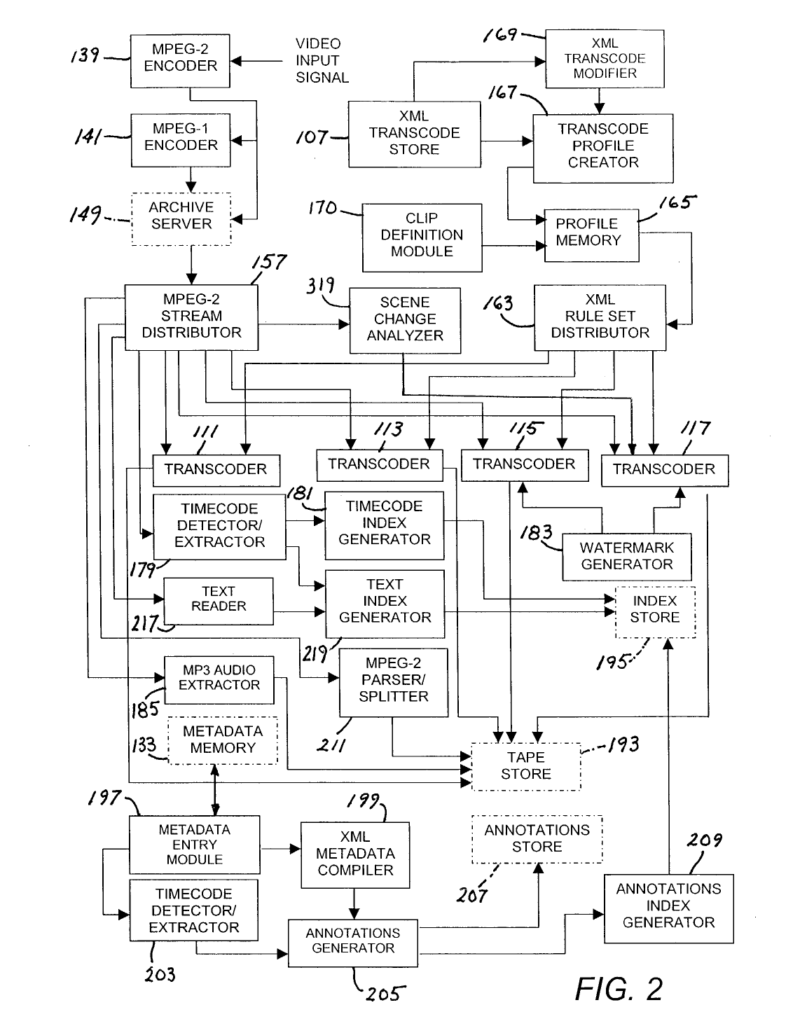

In a first step 101 implemented by an administrator program 103 on a computer 105, an administrator or operator of a video archiving and processing service selects XML transcode rules. A set of transcode rules for the conversion of a media file from one format to one or more other formats is stored by the video archiving and processing service in an XML transcode store or memory 107 of a host computer system, selected functional blocks of which are illustrated in FIG. 2. The client or administrator computer 105 may communicate with the host computer system via the internet for purposes of selecting XML transcode rules for a particular video asset to which access rights have been obtained. The host computer system may be a single computer but for purposes of optimizing processing speed and capacity is preferably several computers operating in one or more known processing modes, for instance, a parallel processing mode, a distributed processing mode, a master-slave processing mode, etc.

In a second step 109 implemented by administrator program 103, the administrator or operator of the video archiving and processing service maps available transcoders 111, 113, 115, 117 (FIG. 2) to respective transcode profiles. In this process, the host computer system (FIG. 2) is provided with instructions as to video formats to be produced by one or more transcoders 111, 113, 115, 117 from the selected or identified video asset. Generally, transcoders 111, 113, 115, 117 can transcode a video asset into any known format including but not limited to compressed data formats such as Unix Bar Archive, Binary and Compact Pro; video data formats such as Windows Media Player, Quicktime Movie, an MPEG Media File; image formats such as Adobe Illustrator, Bitmap, Windows Clipboard, JPEG Picture, MacPaint, Photoshop, Postscript, PageMaker 3; multimedia formats such as ShockWave Movie'; 3D formats such as QuickDraw 3D; audio formats such as MIDI, MPEG 3, Qualcomm Pure Voice; Web formats such as Hypertext Web Page, Java, URL Web Bookmark; Microsoft formats such as Powerpoint formats, Excel formats, Word formats; document formats such as WordPerfect, Rich Text; and Palm OS Application formats.

Subsequently, in a step 119 an encode/logger program 121 on an encoder computer 123 of the video archiving and processing system places the video asset, which is to be ingested or encoded, within the hierarchy. Thus, the asset is placed in its logical location before ever actually being ingested into the system. Other software generally requires a two-step system where an asset file is created and then placed into its proper referential location later.

In a step 125, encoder computer 123 operating under encode/logger program 121 selects external ODBC data for linking or porting. Computer 123 uses machine name or address, table name, field name, and field value in the selection process. Thus, encoder computer 123 determines the format of the video asset to be ingested or encoded by one or more transcoders 111, 113, 115, 117 (FIG. 2). The selection of the external ODBC data for linking or porting facilitates transfer of the video asset, if necessary, from an external source and facilitates transcoding of the video asset pursuant to the transcode profiles created by the administrator or operator.

In a step 127, generic keywords are entered into encoder computer 123 as the piece is encoding. In a subsequent step 129, an operator, typically an employee of the video archiving and processing service, enters meta-data into encoder computer 123. The meta-data includes a description of the video asset, one or more categories, off-line shelf information etc. In the case of sports footage, the description may include the type of sport, the names of the competing parties, the date of the competition, etc. This example might bear a single category, sports. In the case of an entertainment video, several categories might be applicable, including feature film, video short, documentary, comedy, drama, etc., while the description would generally include the title, the release date (if any), the producer, the director, main actors, etc.

The selections made via client/administrator computer 105 may be stored in a local disk store 131 accessible by the client/administrator computer, while the meta-data and other information input via encoder computer 123 may be stored in a local disk store 133 of that host computer.

As depicted in FIG. 1B, encoder software 135 running on encoder computer 123 implements, in a step 137, the definition of a video clip or show to be encoded. The definition includes the in-point or starting frame and the out-point or end frame of the video clip or show. The encoder software 135 modifies generic digital circuits of computer 123 to form a pair of encoders 139 and 141 (FIG. 2) for respectively converting an identified video asset into MPEG-1 and MPEG-2 and optionally other formats simultaneously or substantially simultaneously. This conversion is executed in a step 143 (FIG. 1B).

In steps 145 and 147, encoder computer 123 operating under encode/logger program 121 captures and logs any error information from monitoring scopes and transfers the MPEG-2 and MPEG-1 video data streams from encoders 139 and 141 (FIG. 2) to an archive server 149 (FIG. 2). The error information is viewed at a later time by an operator. Alternatively or additionally, an operator views the monitoring scopes in real time to detect error information. Archive server 149 may take the form of a Unix server (FIG. 1B) accessing, under an archivist program 151, a gigabit Ethernet-switched fiber channel disk store or FC or SCSI tape store 153 for long-term storage of the MPEG-2 and MPEG-1 video data streams.

Archivist program 151 and a transcode server program 155 (FIG. 1B) modify generic digital circuits of Unix archive server 149 to form a data stream distributor 157 (FIG. 2) which functions to distribute one or both of the MPEG-2 and MPEG-1 video data streams in a step 159 (FIG. 1B) to transcoders 111, 113, 115, 117. In another step 161, an XML rule set distributor 163 (FIG. 2) feeds modified XML transcode rule sets to transcoders 111, 113, 115, 117.

As illustrated in FIG. 2, XML rule set distributor 163 is connected to a profile memory 165 that stores transcode profiles, i.e., sets of transcode rules which govern the operation of transcoders 111, 113, 115, 117 in converting a video asset from MPEG-2 (or MPEG-1) into a requested format. The transcode profiles are generated by a transcode profile creator 167 from transcode rules contained in store 107. Transcode profile creator 167 functions in response to instructions provided by an XML transcode modifier 169. Modifier 169 may be called into action in response to an edit request received from a client/administrator computer 105 (FIG. 1A). The transcode profiles are selected from profile memory 165 pursuant to definitions of the selected video clips as provided by a clip definition module 170.

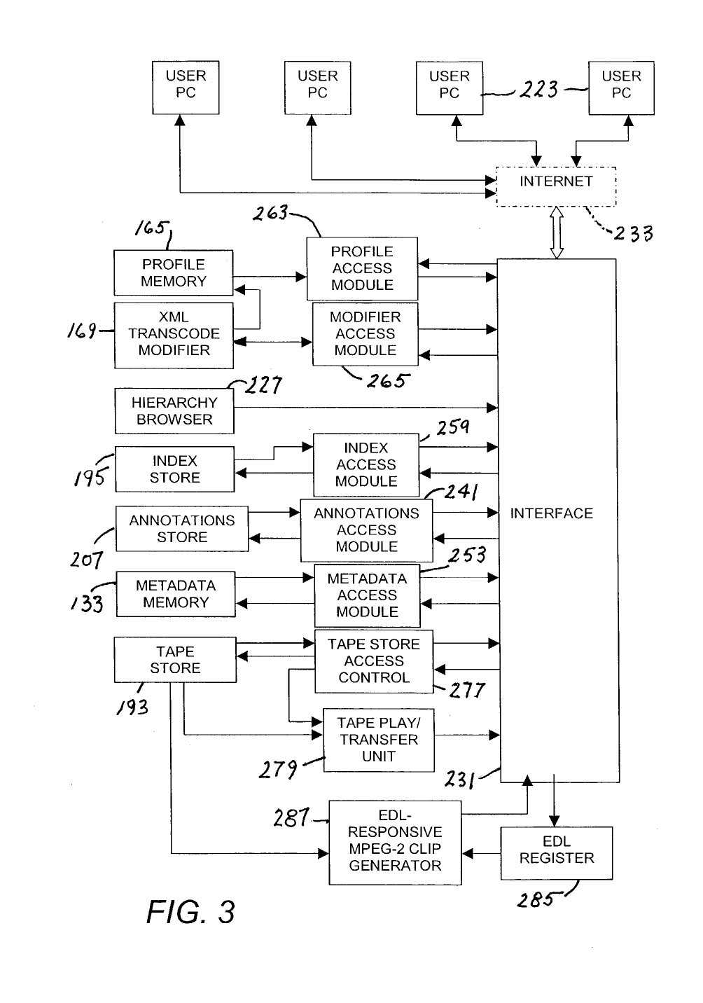

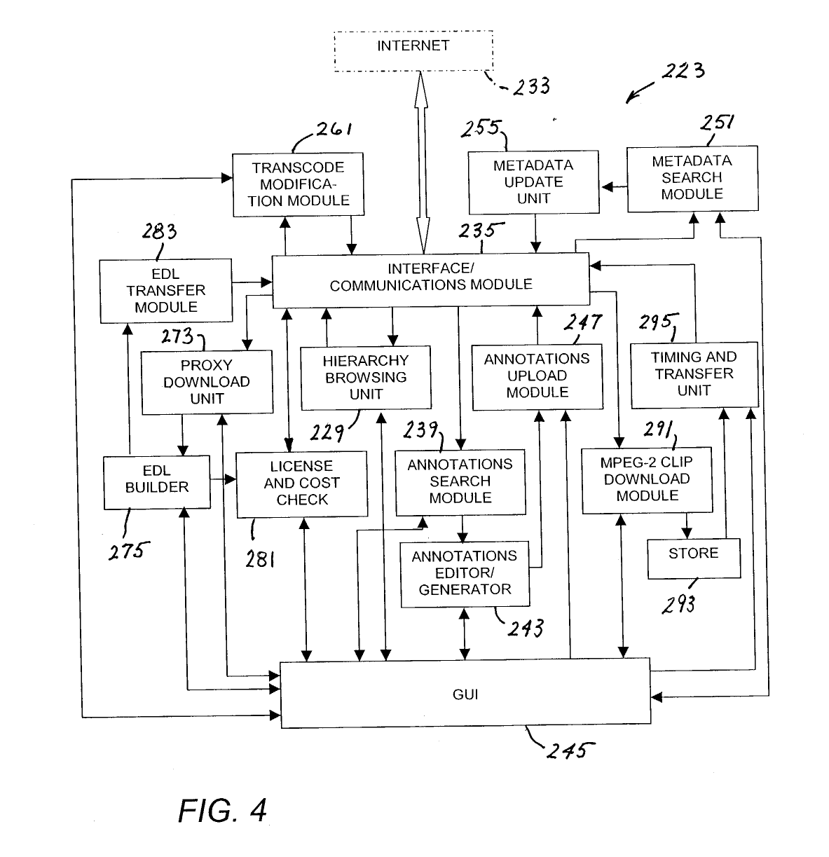

FIG. 1C depicts steps performed by transcoders 111, 113, 115, 117. In particular, a first transcoder 111 may function to generate a Windows Media file in a step 171, while a second transcoder 113, generates a Real file in a step 173. A third transcoder 115 may generate a storyboard MPEG-4 video data steam in a step 175, while a fourth transcoder 117 generates, in a step 177, a storyboard video data stream based on detected scene changes or extracted time code. Transcoder 115 automatically generates an edit decision list (“EDL”) in the process of generating a storyboard MPEG-4 video data steam in step 175. Transcoder 117 operates in response to a user-defined EDL, as discussed in detail hereinafter with reference to FIGS. 3 and 4.

The video archiving and processing system as depicted in FIG. 2 further comprises a time-code detector or extractor 179, a time-code index generator 181, a watermark generator 183, and an MP3 audio extractor 185. These functional modules are realized by generic digital circuits of a transcoder farm 187 (FIG. 1C), i.e., multiple computers, those generic circuits being modified by a transcoder program 189 (FIG. 1C) to form the respective modules.

Time-code detector 179 is connected at an input to data stream distributor 157 for extracting the time code ensconced in the MPEG-2 (or MPEG-1) video data stream. Time-code detector 179 feeds time-code index generator 181 and cofunctions therewith, in a step 190 (FIG. 1C) to build a time code index of the MPEG-2 master video file.

MP3 audio extractor 185 (FIG. 2) also receives the MPEG-2 or MPEG-1 video data stream from distributor 157 and carries out an MP3 audio extraction in a step 191 (FIG. 1C).

The video data streams produced by transcoders 111, 113, 115, 117 are low-resolution video proxies of the high-resolution MPEG-2 version of a subject video asset. The various video proxies may be provided with a watermark by watermark generator 183 on a step 192 (FIG. 1C). The watermarked low-resolution data streams or video proxies produced by transcoders 111, 113, 115, 117, as well as the MP3 audio stream produced by MP3 audio extractor 183, may be stored on magnetic tape media 193 or other permanent storage media such a local disk store 133 (FIGS. 1A-1C). The time-code index produced by generator 181 is registered in an index store 195 (FIG. 2).

As further depicted in FIG. 2, the video archiving and processing system also comprises a meta-data entry module 197 which is realized as generic digital circuits of encoder computer 123 (FIG. 1A) modified by encode/logger program 121. Entry module 197 may capture information from an operator input device, from a text reader 217 (discussed below), or from an external database (not shown). The meta-data is stored in local disk store or memory 133. An XML meta-data compiler 199 is connected to meta-data entry module 197 and/or to disk store 133 for compiling, in a step 201 (FIG. 1C), an XML version of meta-data pertinent to an assimilated or ingested video asset. Meta-data entry module 197 is also connected to a time-code detector/extractor 203 (FIG. 2) in turn linked, together with compiler 199, to an annotations generator 205. Annotations produced by generator 205 are held in an annotations store 207 and indexed by a generator 209. Annotations index generator 209 delivers its output to index store 195. The annotations indices may include identification codes (e.g., time codes) associating the textual material with selected frames of low-resolution video data streams produced by transcoddrs 111, 113, 115, and 117, the identification codes being stored together with the searchable indices.

The video archiving and processing system of FIG. 2 additionally comprises an MPEG-2 parser and splitter 211 operatively coupled to distributor 157 for parsing and splitting the MPEG-2 data stream in a step 213 (FIG. 1C) into subsections for storage on tape media 193. The parsed and split MPEG-2 video data stream, the watermarked low-resolution proxies from transcoders 111, 113, 15, 117, and the MP3 audio stream from MP3 audio extractor 183 are stored on magnetic tape media 193 in a step 215.

XML meta-data compiler 199 and MPEG-2 parser and splitter 211 may be formed as program-modified generic digital processing circuits of Unix archive server 149 (FIG. 1C). An archive manager program 216 forms XML meta-data compiler 199 and MPEG-2 parser and splitter 211 from generic circuits.

As further depicted in FIG. 2, the video archiving and processing system additionally comprises text reader 217 connected at an input to video data stream distributor 157 for receiving therefrom a high-resolution video data stream and analyzing that data stream for textual material. The textual material may be in the form of closed captions and/or subtitles. Alternatively or additionally, textual material may be input to text reader 217 from a source other than video data from distributor 157. The textual material may include annotations from generator 205. In any event, the textual material is related to the content of a video asset encoded in high-resolution MPEG-2 and MPEG-1 data files stored in tape media 193.

Downstream of text reader 217 is provided a text index generator 219 which produces a searchable index of textual material collected via the text reader. The indices produced by generator 219 are maintained in index store 195. The indices may include identification codes (e.g., time codes) associating the textual material with selected frames of the low-resolution video data stream, the identification codes being stored together with the searchable indices.

FIG. 1D depicts several steps performed by or on behalf of a user or customer of the video archiving and processing service implemented by the system of FIG. 2. In general, these steps are implemented via individual user or studio software 221 on a personal computer 223 disposed at a remote location relative to the system computer components depicted in FIG. 2. In a first such step 225, the user browses the system hierarchy such as file directories and other content indicators. This browsing function is implemented at the service end by a browser module 227 (FIG. 3) and at the user end by a hierarchy browsing unit 229 implemented as generic digital processing circuits of computer 223 modified by software 221. System browser module 227 is connected to an interface 231 in turn connected to browsing unit 229 of user PC 223 via the Internet 233 and an interface or communications module 235 of user computer 223.

In another step 237 (FIG. 1D) performed by or on behalf of a user or customer of the video archiving and processing service, time-based annotations are created for a video clip. The user may first access annotations store 207 (FIGS. 2 and 3) to peruse or examine the annotations generated for a subject video asset. To that end, user computer 223 (FIG. 4) includes an annotations search module 239 that accesses annotations store via interface or communications module 235, the Internet 233, interface 231 (FIG. 3), and an annotations access module 241. The user is able to edit the previously stored annotations to create a new set of annotations for a video clip the user intends to have produced, for example, from a stored high-resolution MPEG-2 video data file. An annotations editor or generator 243 of the user computer 223 performs this editing function. Editor/generator 243 is connected to annotations search module 239 for receiving annotations data from store 207, to a graphical user interface 245 or other software for enabling user interaction, and to an annotations upload module 247 for transferring edited annotations, edit instructions, or even new annotations made by the individual user to annotations store 207. Graphical user interface (GUI) 245 is connected to the various functional modules of user computer 223 for enabling user control.

In a further step 249 (FIG. 1D) performed by or on behalf of a user or customer of the video archiving and processing service, the user edits or updates meta-data fields stored with reference to a selected video asset. User computer 223 includes a meta-data search module 251 operatively couplable to meta-data memory 133 (FIGS. 1A, 2, 3) via interface/communications module 235 (FIG. 4), the Internet 233, interface 231, and a meta-data access module 253 (FIG. 3). Meta-data search module 251 receives instructions from GUI 245 and an turn informs a meta-data update unit 255 which may edit or add meta-data fields to memory 133 in respect of a video clip that the user intends to create from a stored MPEG-2 asset.

In a step 257 (FIG. 1D), a user may search the meta-data fields stored in memory 133, the annotations in store 207, or indices in store 195 (FIGS. 2 and 3), using Boolean logic. Index store 195 is perused via an index access module 259 shown in FIG. 3. This searching is in preparation for possible editing and processing operations carried out under direction of a user computer 223. In some cases, for instance, it may be desirable to have a user modify a transcode profile to enable a transcoder 111, 113, 115, 117 to generate a new or different low-resolution version of an ingested video asset. To that end, user computer 223 (FIG. 4) includes a transcode modification module 261 operatively connectable via the Internet 233, interface/communications module 235, and interface 231 to profile memory 165 (FIGS. 2 and 3) via a profile access module 263 and to XML transcode modifier 169 via a modifier access module 265. Thus, if a user needs a low-resolution version of a stored video asset in a specialized format, the user is able to generate a transcode profile typically by modifying a profile already stored in memory 165. This editing, modification or generation of transcode profiles is carried out in processes 267 and 269 (FIG. 1D) where the user request transcode profiles of existing clips and then resubmits a clip to one or more transcoders 111, 113, 115, 117.

In a further step 271 of a video archiving and processing method, as illustrated in FIG. 1E, a user via computer 223 builds a frame-accurate EDL list based on proxies. More specifically, the user downloads proxies from tape media or store 193 (FIGS. 2 and 3) and builds an edit decision list or EDL. To that end, as shown in FIG. 4, user computer 223 includes a proxy download module 273 and an EDL builder 275 connected in cascade to interface/communications module 235. Access to tape media or store 193 is achieved on the service side via a tape store access control 277 and a tape play/transfer unit 279. EDL builder 275 is connected to a license and cost check 281 which functions to check, in a step 282 (FIG. 1E), licensing and cost restrictions for a video clip specified by a constructed EDL. License and cost check 281 communicates with a counterpart (not shown) in the video archiving and processing system.

An EDL generated by user computer 223 and particularly by EDL builder 275 identifies a video asset and designates an in-point and an out-point in the video asset, which will respectively constitute the starting frame and end frame of the video clip. In addition, the EDL may specify a name for the video clip to be produced. Optionally, the user computer 223 may provide instructions for generating or editing textual material to be transmitted with or as part of the video clip.

Upon the downloading of a low-resolution proxy by a user computer 223, tape store access control 277 initiates a transfer, in a prefetching step 284 (FIG. 1E), of the associated high-resolution MPEG-2 version of the video asset from tape media or store 193. This transfer is to an editing tool in the form of an EDL-responsive MPEG-2 clip generator 287 (FIG. 3).

If a proposed video clip, as defined by an EDL generated by builder 275, has acceptable cost restrictions and is suitable available for license, EDL builder 275 transfers the EDL via an EDL transfer module 283 (FIG. 4) to an EDL register 285 (FIG. 3) in the video archiving and processing system. Register 285 is connected on an input side to interface 231 and on an output side to EDL-responsive MPEG-2 clip generator 287 that is in turn connected to tape media or store 193 and to interface 231. Generator 287 already has received at least a portion of the MPEG-2 version of the relevant video asset from tape media or store 193 (prefetching step 282) and creates therefrom an edited clip per the EDL in a step 289. The edited clip may be downloaded to the requesting user computer 223 and particularly to an MPEG-2 clip download module 291 that places the clip in a video data store 293.

User computer 223 may include a timing and transfer unit 295 for sending the new video clip to one or more destinations over the Internet 233 at a predetermined time or times. Alternatively, an EDL produced by builder 275 may include an identification of destination and a time or times of intended transmission. Such EDLs are submitted in steps 297 and 299.

The video clip produced by generator 287 may be posted, pursuant to a user's instructions, to automation or a VOD (video on demand) server in a step 301 or transferred to an output device together with job rules in a step 303. The user typically supplies a target address or other identification of intended recipients, as well as a time or times of desired transmission. If so specified by a user, a created video clip may be played out via a decoder channel at a given time (step 305). If the play-out is controlled, it is necessary to wait for a time code positioning command before playing the referenced file (step 307). If the user's intent is to provide a clip to professional editors, XML control is transmitted to an AVID automation package (step 309). Upon receiving an RS422 play command the clip is transferred. In that case, reference is made to the XML time code information and the AVID digitization process is commenced (step 311). The latter is undertaken by respective hardware 313 with a control program 314, whereas a playback workstation and decoder 315 perform steps 305 and 307 under studio control software 317.

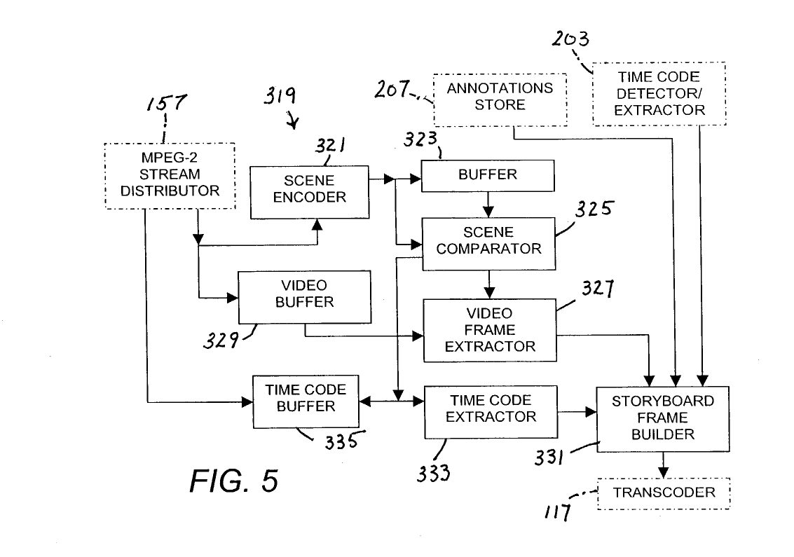

FIG. 5 is a block diagram of components of a scene change analyzer 319 illustrated in FIG. 2, the components typically being realized as generic digital computer circuits modified by programming to performed respective functions. The components indicated in dot-dash lines in FIG. 5 are other components depicted in FIG. 2. Scene change analyzer 319 includes a scene encoder 321 generating, from a high-resolution video data stream from distributor 157, a parameter measuring a preselected characteristic of each successive video frame in the video data stream. The parameter may, for instance, be an average amount of a particular color, or a weighted color average across a color spectrum, or an average light intensity. Alternatively, the parameter may be a vector or set of vectors defining image forms in the video frames. The parameter selected for analysis by scene change analyzer 319 is preferably one that enables detection of IE drastic pans and zooms, as well as new images and cut scenes.

Encoder 321 feeds its output to a buffer 323 and a comparator 325. Comparator 325 compares the parameter for each video frame from encoder 321 with the parameter(s) of one or more immediately succeeding frames, received via buffer 323. Where the parameter is vector based, comparator 325 undertakes a vector analysis to automatically (without human intervention) detect scene changes.

Upon detecting a difference of a pre-established threshold between the parameters of successive frames, comparator 325 issues a trigger signal to a video frame extractor 327. Extractor 327 is connected at an input to a video buffer 329 that temporarily holds several video frames of the high-resolution (MPEG-2) video data stream from distributor 157.

In response to a trigger signal from comparator 325, video frame extractor 327 selects a respective frame from the temporary cache in buffer 329 and forwards that frame to a storyboard frame builder 331. From a time-code extractor 333, frame builder 331 also receives time codes corresponding to the selected frames from video frame extractor 327. Time-code extractor 333 receives input from a time-code buffer 335 in turn connected at an input to stream distributor 157. Scene comparator 327 is linked to time-code buffer 335 and time-code extractor 33 for controlling the shifting of time code data to storyboard frame builder 331 in conjunction with the shifting of video frames thereto.

Storyboard frame builder 331 also receives annotations from annotations store 207 (or generator 205 in FIG. 2) together with associated time codes from time-code detector/extractor 203. This additional input enables storyboard frame builder 331 to associate annotation text with the storyboard frame. Storyboard frame builder 331 may additionally or alternatively be connected directly or indirectly to text reader 217 (FIG. 2) for receiving textual material therefrom.

Storyboard frame builder 331 is connected at an output to transcoder 117 for cooperating therewith in the production of a storyboard in the form of a low-resolution video data stream wherein successive frames each correspond to a respective different scene of the high-resolution video frame data. It is to be noted that scene change analyzer 219 may be incorporated wholly or partially into transcoder 117.

It is to be noted that the scene change analysis may be accomplished via other, related techniques, such as comparing each frame with an average value of two or more previous frames. In another alternative, storyboard frame builder 331 may select frames partially or solely in accordance with time code. For instance, where annotations or textual material indicates a scene change at a certain time code value, the video frame with that time code value may be automatically selected for inclusion in the low-resolution video data stream at the output of transcoder 117.

What is claimed is:

1. A video archiving and processing method comprising:
providing a stream of high-resolution video frame data;
operating at least one digital computer to automatically identify scene changes in successive frames encoded in said video frame data;
automatically generating a storyboard in the form of a low-resolution video data stream wherein successive frames each correspond to a respective different scene of said high-resolution video frame data; and
storing said high-resolution video frame data and said low-resolution video data stream.

2. The method defined in claim 1, further comprising:
providing textual material corresponding to at least some frames of said high-resolution video frame data;
storing said textual material;
automatically generating a searchable index of said textual material, said index including identification codes associating said textual material with selected frames of said low-resolution video data stream; and
storing said searchable index including said identification codes.

3. The method defined in claim 2 wherein the providing of said textual material includes automatically extracting said textual material from text data included in said high-resolution video data.

4. The method defined in claim 3 wherein said text data includes closed caption data.

5. The method defined in claim 3 wherein said text data includes subtitles.

6. The method defined in claim 2 wherein the providing of said textual material includes inputting said textual material from a source other than said high-resolution video data.

7. The method defined in claim 6 wherein said textual material includes annotations related to subject matter of said high-resolution video data.

8. The method defined in claim 2, further comprising:
receiving, from a user computer, a request for a selected portion of the stored textual material;
in response to said request, transmitting said portion of the stored textual material to said user computer;
subsequently receiving from said user computer an edit request;
in response to said edit request, storing an edited version of said portion of the stored textual material.

9. The method defined in claim 2 wherein said identification codes are time codes.

10. The method defined in claim 1 wherein the operating of said computer to automatically identify scene changes includes analyzing changes in color.

11. The method defined in claim 1 wherein the operating of said computer to automatically identify scene changes includes a vector analysis of successive frames of said video frame data.

12. A video archiving and processing method comprising:
providing a stream of high-resolution video frame data;
storing a high-resolution version of said video frame data;
operating at least one digital computer to automatically generate, from said stream of video frame data, a plurality of low-resolution video data streams in respective formats different from each other; and
storing said low-resolution data streams.

13. The method defined in claim 12, further comprising:
providing textual material corresponding to at least some frames of said high-resolution video frame data;
storing said textual material;
automatically generating a searchable index of said textual material, said index including identification codes associating said textual material with selected frames of said low-resolution video data stream; and
storing said searchable index including said identification codes.

14. The method defined in claim 13 wherein the providing of said textual material includes automatically extracting said textual material from text data included in said high-resolution video data.

15. The method defined in claim 14 wherein said text data includes closed caption data.

16. The method defined in claim 14 wherein said text data includes subtitles.

17. The method defined in claim 13 wherein the providing of said textual material includes inputting said textual material from a source other than said high-resolution video data.

18. The method defined in claim 17 wherein said textual material includes annotations related to subject matter of said high-resolution video data.

19. The method defined in claim 13, further comprising:
receiving, from a user computer, a request for a selected portion of the stored textual material;
in response to said request, transmitting said portion of the stored textual material to said user computer;
subsequently receiving from said user computer an edit request;
in response to said edit request, storing an edited version of said portion of the stored textual material.

20. The method defined in claim 13 wherein said identification codes are time codes.

21. The method defined in claim 12 wherein the operating of said computer includes:
selecting sets of transcode rules from a store of possible rules to create transcode profiles for respective ones of said low-resolution video data streams, said transcode profiles corresponding to respective ones of said formats; and
generating said low-resolution video data streams in accordance with the respective transcode profiles.

22. The method defined in claim 21 wherein the operating of said computer further comprises:
receiving transcode-profile instructions from a user computer; and
creating at least one of said transcode-profiles pursuant to said instructions.

23. The method defined in claim 12, further comprising generating said high-resolution version of said video frame data.

24. The method defined in claim 23 wherein the operating of said computer includes generating said low-resolution data streams from said high-resolution version of said video frame data.

25. The method defined in claim 12 wherein at least one of said low-resolution video data streams is a storyboard in the form of a series of video frames representing respective different scenes of said video frame data.

26. The method defined in claim 25 wherein the operating of said computer includes automatically generating said storyboard at least indirectly from said video frame data.

27. The method defined in claim 26 wherein the generating of said storyboard includes a color analysis of video frames in said video frame data.

28. The method defined in claim 26 wherein the generating of said storyboard includes a vector analysis of video frames in said video frame data.

29. The method defined in claim 26 wherein the generating of said storyboard includes detecting time code in said video frame data.

30. The method defined in claim 25 wherein the operating of said computer includes:
detecting time code in said video frame data; and
generating said storyboard in part by selecting frames identified via said time code.

31. The method defined in claim 12 wherein said high-resolution version is in a format taken from the group consisting of MPEG-1 format and MPEG-2 format, the format of at least one of said low-resolution video data streams being taken from the group consisting of Windows Media and Real.

32. The method defined in claim 12, further comprising:
generating a video clip from said high-resolution version of said video frame data, said video clip having a defined in-point or starting frame and a defined out-point or end frame;
storing said video clip; and
transmitting said video clip to another computer in response to a request from a user computer.

33. The method defined in claim 12, further comprising:
accessing at least one of the stored low-resolution video data streams in lieu of the stored high-resolution version of said video frame data;
receiving editing instructions based on the accessed one of the stored low-resolution video data streams; and
in response to the received editing instructions, generating a video clip from the stored high-resolution version of said video frame data.

34. The method defined in claim 12, further comprising:
receiving, from a user computer, a request for a stored low-resolution data stream;
in response to said request, transmitting at least a portion of the requested low-resolution data stream to said user computer;
subsequently receiving from said user computer an edit decision list pertaining to said requested low-resolution data stream;
in response to said edit decision list, automatically generating a video clip from a high-resolution video frame data corresponding to said requested low-resolution data stream, the generated video clip being delimited in accordance with said edit decision list; and
transmitting said video clip to said user computer.

35. A video archiving and processing method comprising:
providing a stream of high-resolution video frame data;
operating at least one digital computer to automatically generate, from said stream of video frame data, at least one low resolution video data stream;
providing textual material corresponding to at least some frames of said high-resolution video frame data;
storing said textual material;
automatically generating a searchable index of said textual material, said index including identification codes associating said textual material with selected frames of said low resolution video data stream; and
storing said searchable index including said identification codes.

36. The method defined in claim 35 wherein the providing of said textual material includes automatically extracting said textual material from text data included in said high-resolution video data.

37. The method defined in claim 36 wherein said text data includes closed caption data.

38. The method defined in claim 36 wherein said text data includes subtitles.

39. The method defined in claim 35 wherein the providing of said textual material includes inputting said textual material from a source other than said high-resolution video data.

40. The method defined in claim 39 wherein said textual material includes annotations related to subject matter of said high-resolution video data.

41. The method defined in claim 35, further comprising:
receiving, from a user computer, a request for a selected portion of the stored textual material;
in response to said request, transmitting said portion of the stored textual material to said user computer;
subsequently receiving from said user computer an edit request;
in response to said edit request, storing an edited version of said portion of the stored textual material.

42. The method defined in claim 35 wherein said identification codes are time codes.

43. A video processing method comprising:
storing a high-resolution version and a low-resolution version of a video asset;
receiving a request from a user computer via a network;
in response to said request, transmitting at least a portion of said low-resolution version of said video asset across said network;
subsequently receiving edit instructions from said user computer pertaining to said video asset;
producing a video clip derived from said high-resolution version of said video asset in response to the received editing instructions; and
transmitting said video clip over said network.

44. The method defined in claim 43, further comprising automatically generating said low-resolution version from said high-resolution version.

45. The method defined in claim 44 wherein said low-resolution version is a storyboard version in the form of a sequence of video frames representing respective scenes of said video asset.

46. The method defined in claim 43, further comprising:
storing textual material relating to said video asset;
storing identification codes associating said textual material with portions of said video asset;
automatically generating a searchable index of said textual material;
storing said index; and
accessing said index in response to a request from said user computer.

47. The method defined in claim 43 wherein the transmitting of said video clip is to a target address and at a transmission time specified by instructions received from said user computer.

48. The method defined in claim 43, further comprising commencing a retrieval of said high-resolution version from storage prior to the receiving of said edit instructions.

49. The method defined in claim 43 wherein said high-resolution version of said video asset includes a plurality of different scenes, said video clip including fewer than all of said scenes.

50. A video processing method comprising:
storing (i) a high-resolution version of a video asset, (ii) a low-resolution version of said video asset, (iii) textual material pertaining to said video asset; and (iv) a searchable index of said textual material;
receiving a request from a user computer via a network;
in response to said request, transmitting across said network at least one of (a) a portion of said low-resolution version of said video asset, (b) a portion of said textual material, and (c) a portion of said index;
subsequently receiving edit instructions from said user computer to generate a video clip from said high-resolution version of said video asset;
prior to the receiving of said edit instructions, commencing a retrieval of said high-resolution version from storage.

51. The method defined in claim 50, further comprising automatically generating said low-resolution version from said high-resolution version.

52. The method defined in claim 51 wherein said low-resolution version is a storyboard version in the form of a sequence of video frames representing respective scenes of said video asset.

53. The method defined in claim 50, further comprising automatically generating said index from said textual material.

54. The method defined in claim 50, further comprising:
generating said video clip from said high-resolution version of said video asset; and
transmitting said video clip to a target address and at a transmission time specified by instructions received from said user computer.

55. The method defined in claim 43 wherein said high-resolution version of said video asset includes a plurality of different scenes, said video clip including fewer than all of said scenes.

56. A video archiving and processing apparatus comprising:
a video input receiving a stream of high-resolution video frame data;
at least one digital computer operatively connected to said video input for analyzing said stream of high-resolution video frame data to automatically identify scene changes in successive frames encoded in said video frame data and for automatically generating a storyboard in the form of a low-resolution video data stream wherein successive frames each correspond to a respective different scene of said high-resolution video frame data; and
a memory operatively connected to said computer for storing said high-resolution video frame data and said low-resolution video data stream.

57. The apparatus defined in claim 56 wherein said computer is programmed to generate a searchable index of textual material corresponding to at least some frames of said high-resolution video frame data, said index including identification codes associating said textual material with selected frames of said low-resolution video data stream, said computer being connected to said memory for storing therein said searchable index including said identification codes.

58. The apparatus defined in claim 57 wherein said computer is further programmed to automatically extract said textual material from text data included in said high-resolution video data.

59. A video archiving and processing apparatus comprising:
a video input receiving a stream of high-resolution video frame data;
at least one digital computer operatively connected to said video input for generating, from said stream of video frame data, a plurality of low-resolution video data streams in respective formats different from each other; and
a memory operatively connected to said computer for storing said low-resolution data streams and a high-resolution version of said video frame data.

60. The apparatus defined in claim 59 wherein said computer is programmed to generate a searchable index of textual material corresponding to at least some frames of said high-resolution video frame data, said index including identification codes associating said textual material with selected frames of said low-resolution video data stream, said computer being connected to said memory for storing therein said searchable index including said identification codes.

61. The apparatus defined in claim 60 wherein said computer is further programmed to automatically extract said textual material from text data included in said high-resolution video data.

62. A video processing apparatus comprising:
a memory storing a high-resolution version and a low-resolution version of a video asset;
an interface for receiving a request from a user computer via a network, said interface being operatively connected to said memory for extracting at least a portion of said low-resolution version of said video asset from said memory and transmitting said portion of said low-resolution version of said video asset across said network; and
an editing tool operatively connected to said interface and said memory for generating, in response to editing instructions received from said user computer over said network, a video clip from said high-resolution version of said video asset.

63. A video processing apparatus comprising:
a memory storing (i) a high-resolution version of a video asset, (ii) a low-resolution version of said video asset, (iii) textual material pertaining to said video asset; and (iv) a searchable index of said textual material;
an interface for receiving a request from a user computer via a network, said interface being connected to said memory for accessing said memory to transmit, in response to said request and across said network, at least one of (a) a portion of said low-resolution version of said video asset, (b) a portion of said textual material, and (c) a portion of said index;
a memory access unit operatively connected to said memory and said interface for commencing a retrieval of said high-resolution version from said memory upon the receiving of said request and prior to the receiving of edit instructions from said user computer to generate a video clip from said high-resolution version of said video asset.
